(19) United States
(12) Patent Application Publication
(10) Pub. No.: US 2006/0237758 A1
(43) Pub. Date: Oct. 26, 2006

(54) Semiconductor device

(76) Inventor: Hideyuki Kinoshita, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/410,012

(22) Filed: Apr. 25, 2006

(30) Foreign Application Priority Data
Apr. 26, 2005 (JP) 2005-128229

(51) Int. Cl. H01L 29/94

(52) U.S. Cl. 257/296

(57) ABSTRACT

A semiconductor device includes a plurality of first active areas arranged in a first area including a first sub area, a second sub area located adjacent to the first sub area in a first direction, and a third sub area adjacent to the first sub area in a second direction perpendicular to the first direction, the plurality of first active areas extending in the second direction, having the same width and being partitioned by a plurality of first isolation areas having the same width, a second active area located in a second area located adjacent to the second sub area in the second direction and adjacent to the third sub area in the first direction, the second active area being wider than the first active area, and a plurality of control gate lines provided in the first and second sub areas and extending in the first direction.

### CROSS-REFERENCE TO RELATED APPLICATIONS

This application is based upon and claims the benefit of priority from prior Japanese Patent Application No. 2005-128229, filed Apr. 26, 2005, the entire contents of which are incorporated herein by reference.

### BACKGROUND OF THE INVENTION

1. Field of the Invention

The present invention relates to a semiconductor device.

2. Description of the Related Art

NAND type flash memories are known as nonvolatile semiconductor memory devices (see, for example, Jpn. Pat. Appln. KOKAI Publication No. 11-26731). In a memory cell array area in such a nonvolatile semiconductor memory device, the widths of each active area and each isolation area are minimized in order to increase the degree of integration of the memory cell array. Further, a relatively wide active area is provided between memory cell array areas in order to provide an area required to form contacts and the like.

The active areas and the isolation areas are periodically arranged in the memory cell array area. This enables an increase in photolithography resolution. However, in the boundary portion between the wide active area, required to form contacts and the like, and the narrow active area, provided in the memory cell array area, an optical proximity effect or the like prevents an increase in resolution. Thus, the isolation area needs to be wider at the boundary between the wide active area and the narrow active area.

In the nonvolatile semiconductor memory device, control gate lines (word lines) are normally formed so as to fill the spaces between floating gates located adjacent to each other in a direction in which the word lines extend (the spaces are located above the isolation areas). However, each control gate line crosses the wide isolation area and the narrow isolation area which is formed in the memory cell array area. This presents various problems such as the prevention of proper formation of control gate lines.

For example, it is assumed that each control gate line is formed of polysilicon and tungsten silicide so as to have a two-layer structure. In this case, the spaces above the wide isolation areas cannot be filled with the polysilicon completely, which may result in the formation of recesses. Thus, when the tungsten silicide is thermally treated, grains of the tungsten silicide are formed on the opposite sides of each recess. This may lead to an open circuit. Further, the tungsten silicide is thicker in the area in which the recess is formed. Consequently, when the pattern of the control gate lines is formed, unwanted parts of the tungsten silicide or polysilicon layer may remain instead of being perfectly etched.

Thus, a problem with the conventional nonvolatile semiconductor memory device is that the control gate lines cannot be appropriately formed because they cross both the wide and narrow active areas. This makes it difficult to obtain a semiconductor device offering stable characteristics and a high yield.

### BRIEF SUMMARY OF THE INVENTION

A semiconductor device in accordance with an aspect of the present invention comprises a plurality of first active areas arranged in a first area including a first sub area, a second sub area located adjacent to the first sub area in a first direction, and a third sub area adjacent to the first sub area in a second direction perpendicular to the first direction, the plurality of first active areas extending in the second direction, having the same width and being partitioned by a plurality of first isolation areas having the same width; a second active area located in a second area located adjacent to the second sub area in the second direction and adjacent to the third sub area in the first direction, the second active area being wider than the first active area; a plurality of control gate lines provided in the first and second sub areas and extending in the first direction; and a plurality of floating gates provided between the first active areas and the control gate lines.

### BRIEF DESCRIPTION OF THE SEVERAL VIEWS OF THE DRAWING

FIG. 1 is a plan view schematically showing the configuration of a nonvolatile semiconductor memory device in accordance with an embodiment of the present invention;

FIG. 2 is a diagram showing an equivalent circuit of the nonvolatile semiconductor memory device in accordance with the embodiment of the present invention;

FIG. 3 is a plan view showing a part of FIG. 1;

FIG. 4 is a diagram showing an active area shown in FIG. 3;

FIG. 5 is a sectional view taken along line A-A′ in FIG. 3;

FIG. 6 is a sectional view taken along line B-B′ in FIG. 3;

FIG. 7 is a sectional view taken along line C-C′ in FIG. 3;

FIG. 8 is a sectional view taken along line D-D′ in FIG. 3;

FIG. 9 is a sectional view taken along line E-E′ in FIG. 3;

FIG. 10 is a diagram schematically showing the positional relationship among areas in accordance with the embodiment of the present invention; and

FIG. 11 is a plan view schematically showing a nonvolatile semiconductor memory device in a comparative example.

### DETAILED DESCRIPTION OF THE INVENTION

An embodiment of the present invention will be described below with reference to the drawings.

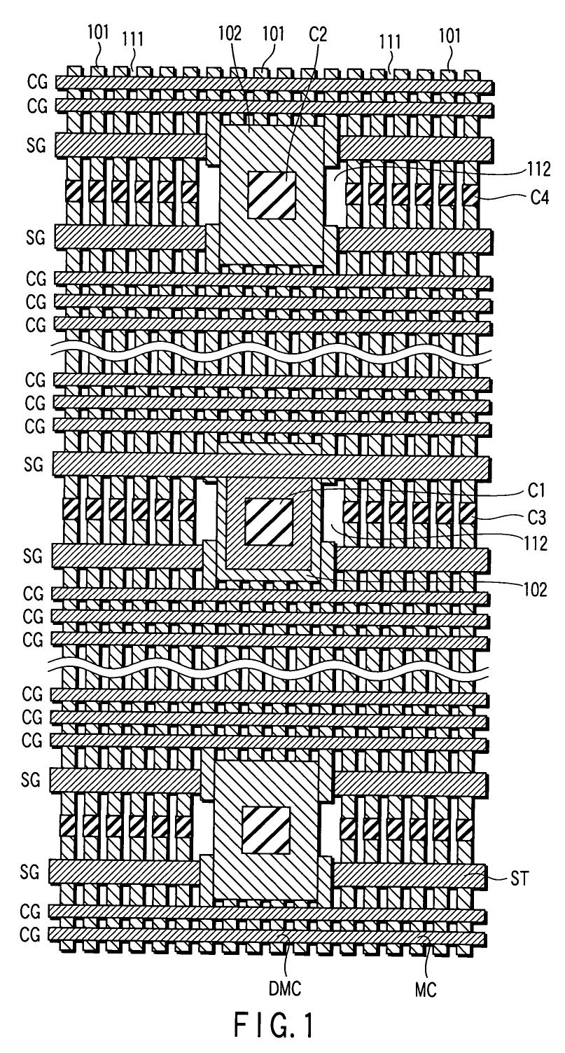

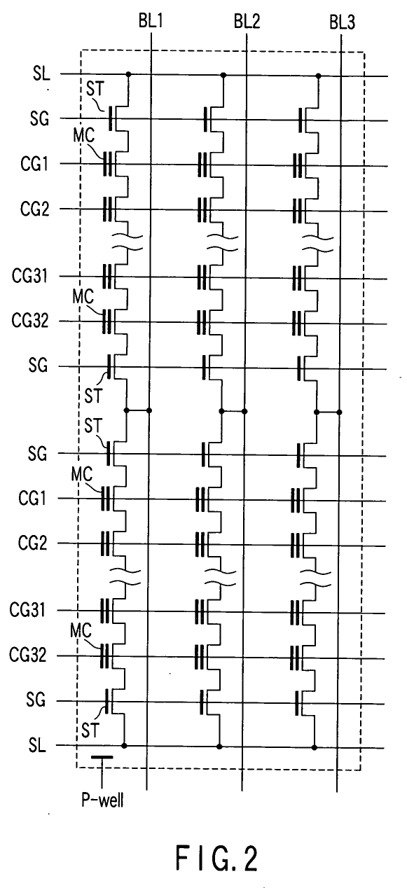

FIG. 1 is a plan view schematically showing the configuration of a nonvolatile semiconductor memory device (NAND type flash memory) in accordance with an embodiment of the present invention. FIG. 2 is a diagram showing an equivalent circuit of the nonvolatile semiconductor memory device shown in FIG. 1. However, FIG. 1 does not show bit lines, source lines, or the like.

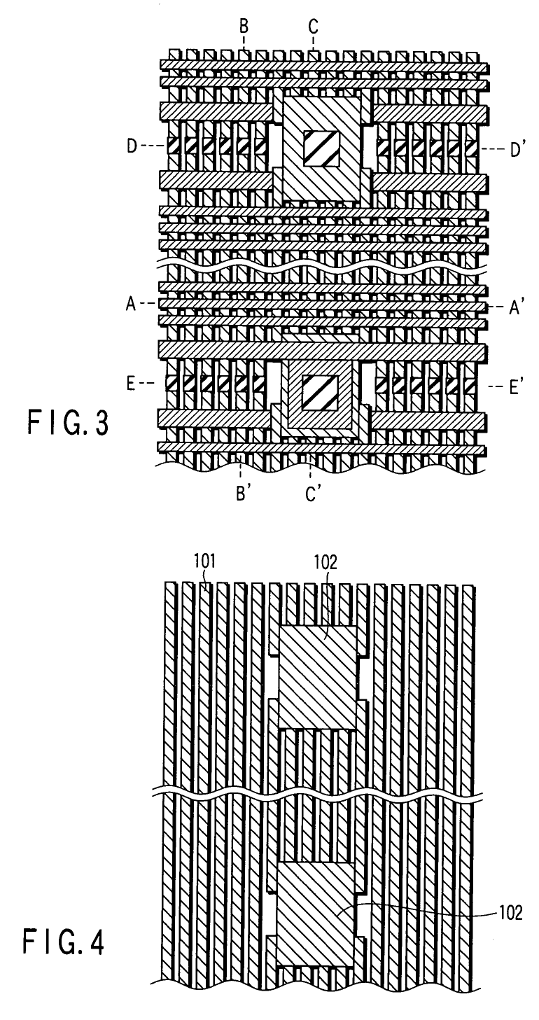

FIG. 3 is a diagram showing a part of FIG. 1.

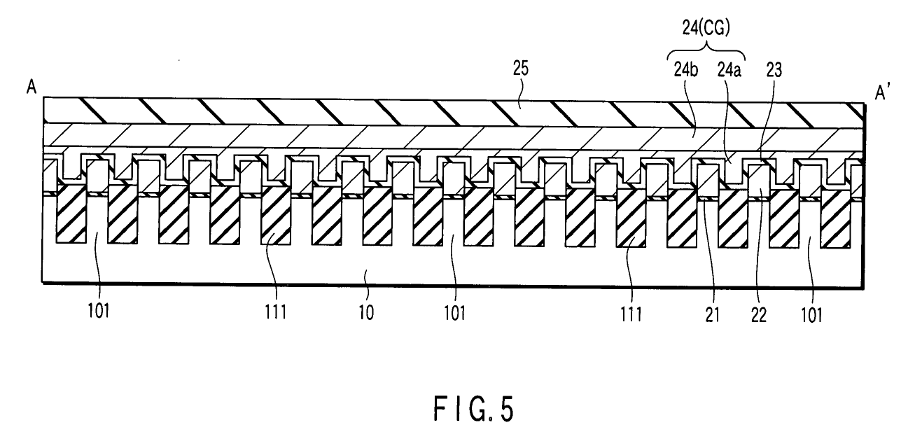

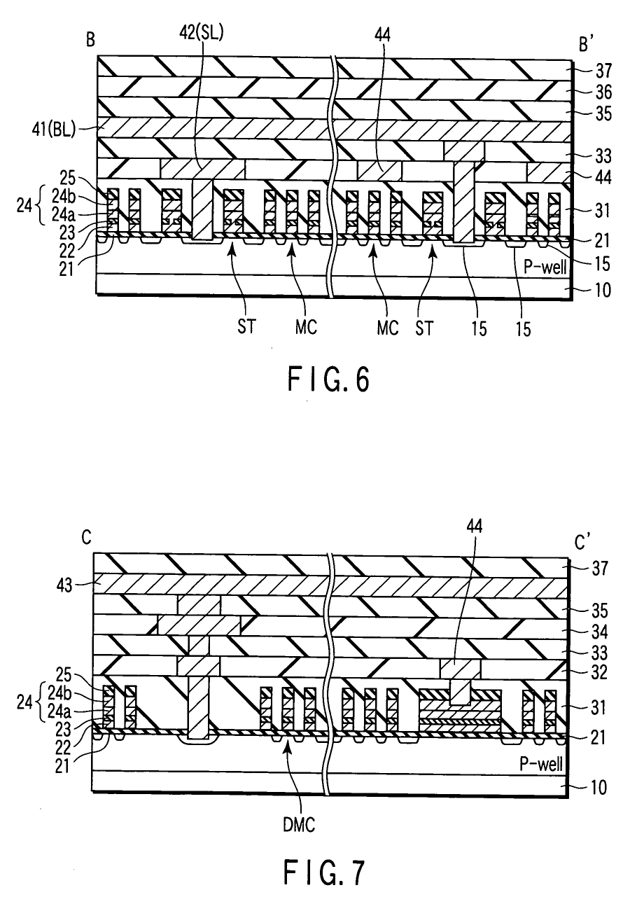

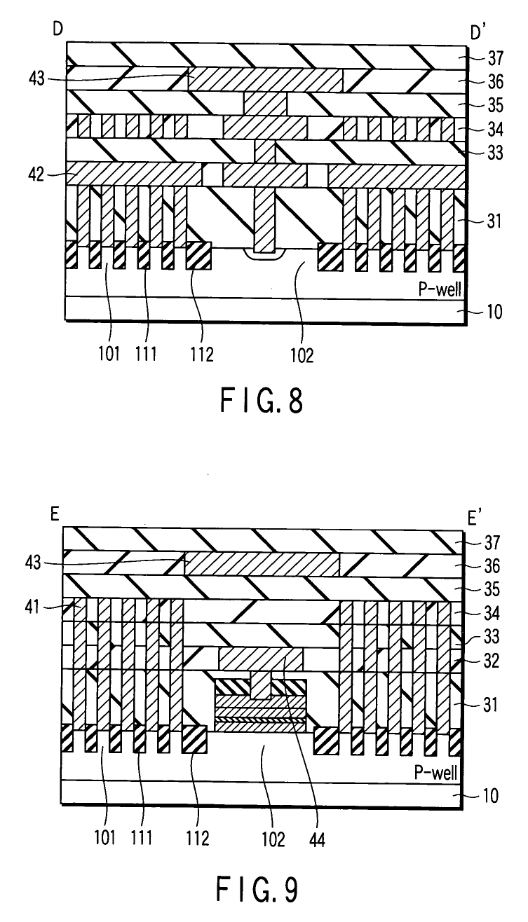

FIG. 4 is a diagram showing an active area shown in FIG. 3. FIG. 5 is a sectional view taken along line A-A′ in FIG. 3. FIG. 6 is a sectional view taken along line B-B′ in FIG. 3. FIG. 7 is a sectional view taken along line C-C′ in FIG. 3. FIG. 8 is a sectional view taken along line D-D′ in FIG. 3. FIG. 9 is a sectional view taken along line E-E′ in FIG. 3. FIGS. 6 to 9 also show the bit lines, source lines, and the like.

As shown in FIGS. 1 and 2, each NAND cell unit has a plurality of memory cells MC connected in series between select transistors ST. A select gate line SG is connected to each of the select transistors ST. Control gate lines (word lines) CG (CG1 to CG32) are connected to the memory cells MC. A bit line (BL1, BL2, . . . ) is connected to one of the select transistors ST. A source line SL is connected to the other select transistor ST.

A P-well in the semiconductor substrate (silicon substrate or the like) 10 is provided with active areas (first active areas) 101 arranged in first areas and active areas (second active areas) 102 arranged in second areas each enclosed by the first areas. The active areas 101 are provided to form the memory cells MC and select transistors ST. Accordingly, to increase the degree of integration, each of the active areas 101 is formed to be relatively narrower in a direction in which the word lines extend (first direction; hereinafter referred to as a word line direction). On the other hand, each of the active areas 102 is relatively wider in the word line direction in order to provide an area required to form contact portions C1 and C2 and the like. In the conventional nonvolatile semiconductor memory device, as shown in the comparative example in FIG. 11, the wide active area 102 is not separated into pieces but is formed to extend continuously in a direction in which the bit lines extend (second direction; hereinafter referred to as a bit line direction). The control gate lines (word lines) CG thus cross the wide active area. In the present embodiment, the wide active areas 102 are discontinuous in the bit line direction, and the narrow active areas 101 are provided between the active areas 102 located adjacent to each other in the bit line direction. Thus, the control gate lines (word lines) CG do not cross the wide active area 102.

The active areas 101 extend in the bit line direction and are partitioned by isolation areas (first isolation areas) 111. Each of the isolation areas 101 has an STI (Shallow Trench Isolation) structure in which an isolation trench is filled with an insulating material. The active areas 101 are arranged at the same pitch in the word line direction. The active areas 101 have the same width, and the isolation areas 111 have the same width. The width of the active area 101 may be the same as or different from that of the isolation area 111.

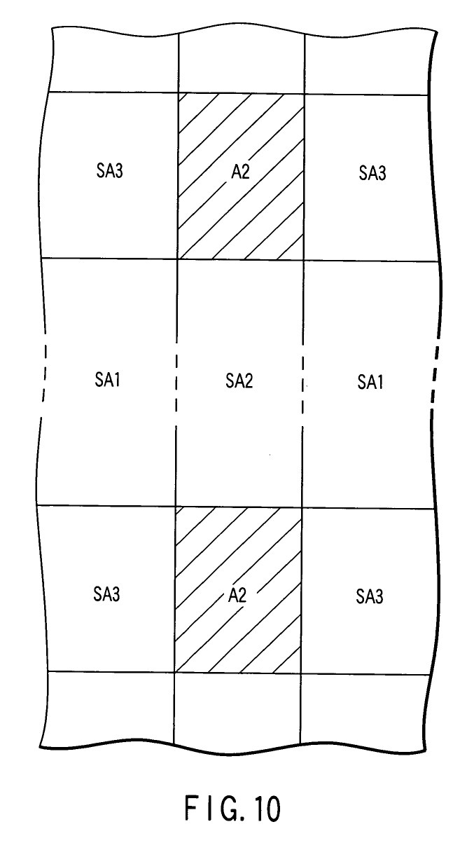

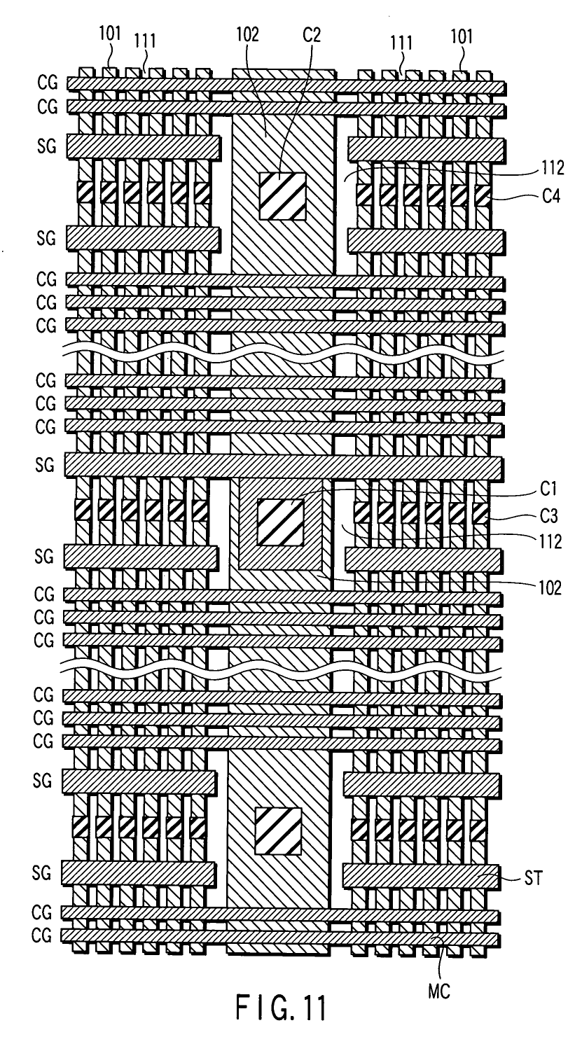

The first area in which the active areas 101 are located has a first sub area, a second sub area located adjacent to the first sub area in the word line direction, and a third sub area located adjacent to the first sub area in the bit line direction. FIG. 10 is a diagram schematically showing the positional relationship between a second area A2 and each of the first sub area SA1, second sub area SA2, and third sub area SA3.

The active area 102 and the active area 101 located in the third sub area are separated from each other by the isolation area (second isolation area) 112. The isolation area 112 is wider than the isolation area 111 (in the word line direction). That is, in the first area, the active areas 101 and the isolation areas 111 are periodically arranged, which enables an increase in the resolution of photolithography. However, since the wide active area 102 is located within this periodic pattern and disturbs the periodicity, the resolution cannot be increased at the boundary between the active areas 101 and 102 owing to an optical proximity effect and the like. The isolation area 112 is thus wider at the boundary between the active areas 101 and 102.

The control gate lines CG are provided in the first and second sub areas. A memory cell is formed at a position corresponding to the intersecting point between the control gate line CG and the active area 101. The select gate line SG is provided in the third sub area. The select transistor ST is formed at a position corresponding to the intersecting point between the select gate line SG and the active area 101. The memory cell MC formed in the first sub area is connected to the corresponding bit line and thus involved in a memory cell selecting operation. The memory cell formed in the second sub area (dummy memory cell DMC) is not connected to any bit line and is thus not involved in the memory cell selecting operation.

As shown in FIGS. 5 to 7, the memory cell MC and the dummy memory cell DMC each comprise a tunnel insulating film 21 formed on the semiconductor substrate 10, a floating gate electrode 22 formed of a polysilicon film, an inter-electrode insulating film 23, and a control gate electrode 24 formed of a stack film of a polysilicon film 24a and a tungsten silicide film 24b. The control gate electrode 24 extends in the word line direction so as to form the control gate line CG. A silicon nitride film 25 is formed on the control gate electrode (control gate line) 24; the silicon nitride film 25 is used as a mask when the control gate line is processed. A source/drain impurity diffusion layer 15 is formed between the memory cells MC located adjacent to each other in the bit line direction and between the memory cell MC and the select transistor ST.

As shown in FIG. 5, a top surface of the isolation area 111 is located below a top surface of the floating gate electrode 22. Consequently, polysilicon film 24a of the control gate line 24 fills the space between the floating gate electrodes 22 located adjacent to each other in the word line direction.

In the conventional nonvolatile semiconductor memory device, the wide active area 102 is formed so as to extend continuously in the bit line direction as already described. The control gate lines (CG) 24 thus cross the wide active area. Thus, the space on the isolation area 112 cannot be completely filled with the polysilicon film 24a. Instead, recesses may be formed. This may pose various problems such as those described in the related art section, thus possibly preventing control gate lines from being appropriately formed.

In the present embodiment, the wide active area 102 is discontinuous in the bit line direction. Thus, the control gate lines (CG) 24 do not cross the wide active area 102. That is, the narrow active areas 101 are provided in the area (second sub area) between the active areas 102 located adjacent to each other in the bit line direction. As shown in FIG. 5, the pitch and width of the narrow active area 101 are equal between the first sub area and the second sub area. This enables the avoidance of the above problems, thus making it possible to form appropriate control gate lines 24.

The memory cell MC, the dummy memory cell DMC, the select transistor ST, and the like are covered with an interlayer insulating film 31. A plurality of interlayer insulating films 32 to 37 are formed on the interlayer insulating film 31. The following are formed in the interlayer insulating films 31 to 37: a bit line (BL) 41, a source line (SL) 42, a well potential line 43, a select gate connection wire 44, and the like.

The bit line 41 is connected to a source/drain diffusion layer 15 in the select transistor ST provided at one end of the NAND cell unit. The source line 42 is connected to the source/drain diffusion layer 15 in the select transistor ST provided at the other end of the NAND cell unit. As shown in FIG. 1, the bit line 41 is connected at a bit line contact portion C3. The source line 42 is connected at a source line contact portion C4.

A well potential line 43 provides the P-well in the semiconductor substrate 10 with a well potential. The well potential line 43 is connected at the contact portion C2. A select gate connection wire 44 connects the select gate lines SG provided in different blocks. The select gate connection wire 44 is connected at the contact portion C1. Large-sized contact holes need to be formed in the contact portions C1 and C2. Thus, as already described, the contact portions C1 and C2 are formed in the wide active area 102.

The nonvolatile semiconductor memory device in accordance with the present embodiment is configured as described above. The second area in which the wide active area 102 is located is enclosed by the first area in which the narrow active areas 101 are located. Thus, the control gate lines CG do not cross the wide active area 102 but only the narrow active areas 101, which have the same pitch and the same width. This makes it possible to prevent problems that may result from the control gate lines CG crossing both the narrow active areas 101 and wide active areas 102. For example, it is possible to prevent the control gate lines CG from crossing recesses resulting from the wide isolation area 112. As a result, control gate lines can be appropriately formed to provide a semiconductor device offering stable characteristics and a high yield.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a plurality of first active areas arranged in a first area including a first sub area, a second sub area located adjacent to the first sub area in a first direction, and a third sub area adjacent to the first sub area in a second direction perpendicular to the first direction, the plurality of first active areas extending in the second direction, having the same width and being partitioned by a plurality of first isolation areas having the same width;
a second active area located in a second area located adjacent to the second sub area in the second direction and adjacent to the third sub area in the first direction, the second active area being wider than the first active area;
a plurality of control gate lines provided in the first and second sub areas and extending in the first direction; and
a plurality of floating gates provided between the first active areas and the control gate lines.

2. The semiconductor device according to claim 1, wherein a contact portion is provided in the second area.

3. The semiconductor device according to claim 1, wherein a second isolation area wider than the first isolation area is provided at a boundary between the third sub area and the second active area.

4. The semiconductor device according to claim 1, wherein the control gate line fills a space between the floating gates located adjacent to each other in the first direction.

5. The semiconductor device according to claim 1, wherein a plurality of memory cells performing memory operations are formed in the first sub area.

6. The semiconductor device according to claim 1, wherein a plurality of dummy memory cells not performing any memory operations are formed in the second sub area.

7. The semiconductor device according to claim 1, wherein a select transistor is formed in the third sub area.

8. The semiconductor device according to claim 1, wherein a select gate line is formed in the third sub area.

9. The semiconductor device according to claim 1, wherein a bit line contact portion is provided in the third sub area.

10. The semiconductor device according to claim 9, wherein a contact portion which is larger than the bit line contact portion is provided in the second area.

11. The semiconductor device according to claim 1, wherein a source line contact portion is provided in the third sub area.

12. The semiconductor device according to claim 11, wherein a contact portion which is larger than the source line contact portion is provided in the second area.

13. The semiconductor device according to claim 1, wherein the control gate line is not formed in the second area or the third sub area.

14. The semiconductor device according to claim 1, wherein the control gate line is formed of a polysilicon film and a silicide film formed on the polysilicon film.

15. The semiconductor device according to claim 14, wherein the polysilicon film fills a space between the floating gates located adjacent to each other in the first direction and is flattened.

16. The semiconductor device according to claim 1, wherein the first isolation area has an STI structure.

17. The semiconductor device according to claim 1, wherein the semiconductor device includes a NAND type nonvolatile memory.
